(19) United States
(12) Patent Application Publication
(10) Pub. No.: US 2010/0263920 A1
(43) Pub. Date: Oct. 21, 2010

(54) Electrical device and method of manufacturing thereof

(75) Inventors: Paul Westmarland, Anglesey (GB); Carl Justin Lewis, Conwy (GB); Andy Sayle, Conwy (GB)

Correspondence Address: DeMont & Breyer, LLC, 100 Commons Way, Ste. 250, Holmdel, NJ, 07733, US

(73) Assignee: DEEPSTREAM TECHNOLOGIES LTD., Gwynedd (GB)

(21) Appl. No.: 12/669,196

(22) PCT Filed: Jul. 16, 2008
(86) PCT No.: PCT/GB2008/002407

§ 371 Date: Jun. 30, 2010

(30) Foreign Application Priority Data
Jul. 18, 2007 (GB) 0714033.8

(51) Int. Cl. H05K 1/09; H05K 1/00; H05K 1/11; H05K 13/00

(52) U.S. Cl. 174/257; 174/250; 174/262; 264/104

(57) ABSTRACT

A three-dimensional circuit substrate comprises one or more electrically conductive tracks. The substrate is formed from a unitary moulding over the one or more electrically conductive tracks and thereby provides structural support therefor.

The present invention relates to electrical devices and particularly to reducing the size whilst maintaining or increasing the functionality of electrical devices and more particularly to forming three-dimensional circuit substrates to improve the functionality of electrical devices.

Within the electrical switchgear and circuit protection and monitoring industries there is an increasing drive and desire to reduce the size of electrical devices and to integrate more functionality into the devices. The shape and functionality of devices such as, for example, circuit breakers, residual current devices, ground fault interrupters and arc fault interrupters, has remained unchanged for years.

Increasing the functionality of such electrical devices typically involves integration of electronic components. However, for known electrical devices, this leads to the problem of insufficient internal surface area to accommodate additional printed circuit boards, or other similar substrates, required to enable the increased functionality, while maintaining or reducing the external size of the device.

### SUMMARY OF INVENTION

According to a first aspect of the present invention there is provided a three-dimensional circuit substrate comprising one or more electrically conductive tracks wherein the substrate is formed from a unitary moulding over the one or more electrically conductive tracks and thereby provides structural support therefor.

At least one portion of the one or more electrically conductive tracks is advantageously disposed on a different plane relative to other portions of the same electrically conductive track. Additionally, at least one portion of the one or more electrically conductive tracks may advantageously be disposed at an angle relative to one or more other portions of the same electrically conductive track. The one or more electrically conductive tracks may form one or more three-dimensional electrically conductive tracks having a plurality of levels. The external three-dimensional shape of the electrical circuit may be determined generally by the peripheral three-dimensional shape formed by the one or more electrically conductive tracks.

The one or more electrically conductive tracks may be formed from a plurality of portions wherein one or more portions may be formed from different materials and/or thicknesses depending on the electrical and structural requirements and the application of the electrical device.

At least one of the one or more electrically conductive tracks may comprise a coin, or localised engraving, to provide a key, or anchor, into the moulded substrate.

The substrate advantageously comprises at least one component aperture which extends through the substrate for attachment of an electrical component to one or more of the electrically conductive tracks at a predetermined position thereon.

The substrate may further comprise location means for determining positional certainty when combining two or more parts to form the electrical device. The location means may be integrally formed with the substrate.

The location means may be formed from a second moulding process.

At least one of the one or more electrically conductive tracks may be formed to contribute to the structural integrity of the electrical device.

The substrate may further comprise attachment means for attaching two or more parts to the substrate to form an electrical device therefrom.

The attachment means is preferably mechanical.

The attachment means may be integrally formed with the substrate.

The attachment means may be formed from a second moulding process.

The material from which the, or each, electrically conductive track is formed may advantageously be of a relatively similar coefficient of thermal expansion as the material from which the support body is formed.

The electrically conductive tracks are advantageously formed from a metal such as, for example, a copper alloy.

According to a second aspect of the present invention there is provided an electrical device comprising an electrical circuit as described above in the preceding paragraphs of the Summary of Invention.

According to a third aspect of the present invention there is provided a method of manufacturing a three-dimensional circuit substrate comprising the steps of: providing an electrically conductive material; forming the electrically conductive material into one or more electrically conductive tracks of a predetermined circuit design; providing a mould of a predetermined shape to correspond with the predetermined circuit design; moulding a unitary substrate over the electrically conductive tracks to provide support therefor.

The step of forming one or more electrically conductive tracks may comprise forming at least one portion of the one or more electrically conductive tracks onto a different plane relative to other portions of the same electrically conductive track. Additionally, at least one portion of the one or more electrically conductive tracks may advantageously be formed at an angle relative to one or more other portions of the same electrically conductive track. The one or more electrically conductive tracks may be formed into one or more three-dimensional electrically conductive tracks having a plurality of levels. The external three-dimensional shape of the electrical circuit may be determined generally by the peripheral three-dimensional shape provided by the forming of the one or more electrically conductive tracks.

The one or more electrically conductive tracks may be formed from a plurality of portions wherein one or more portions may be formed from different materials and/or thicknesses depending on the electrical and structural requirements and the application of the electrical device.

Prior to the moulding step, a coin or localised engraving may be formed on one or more of the electrically conductive tracks to provide a key, or anchor, into the moulded substrate upon moulding thereof.

Also prior to the moulding step, component attachment means may be disposed on the electrically conductive track in predetermined positions to correspond with the predetermined circuit design. The component attachment means may comprise solder pads.

Advantageously, the moulding step may further comprise the forming of at least one component aperture in the substrate, which extends through the substrate to provide access for attachment of an electrical component to one or more of the electrically conductive tracks at a predetermined position thereon.

The moulding step may further comprise forming locating means for determining positional certainty when combining two or more parts to form the electric circuit device. The moulding step may further comprise forming attachment means for attaching the electric circuit device to another part to form an electrical device, or for forming attachment means for attaching to corresponding attachment means on a second electric circuit device. The attachment means may be mechanical attachment means, or may additionally be part of electrical connection means for electrically connecting the electric circuit device to a second electric circuit device.

The locating means and attachment means may be formed integrally with the substrate.

The locating means and attachment means may be formed with a secondary moulding process.

The method of manufacturing the electric circuit device may further comprise populating the electrically conductive track, via the at least one component aperture, with electric components corresponding with the predetermined circuit design. The electric components may be attached to the electrically conductive track using the component attachment means.

The material from which the, or each, electrically conductive track is formed may advantageously be of a relatively similar coefficient of thermal expansion as the material from which the support body is formed. The, or each, electrically conductive track is advantageously formed from a electrically conductive metal and preferably comprises copper such as, for example, a copper alloy.

The support body is formed from a plastics material such as, for example, engineering thermoplastic. The method of moulding is advantageously injection moulding.

### DESCRIPTION

The present invention will now be described with reference to the accompanying drawings, in which:

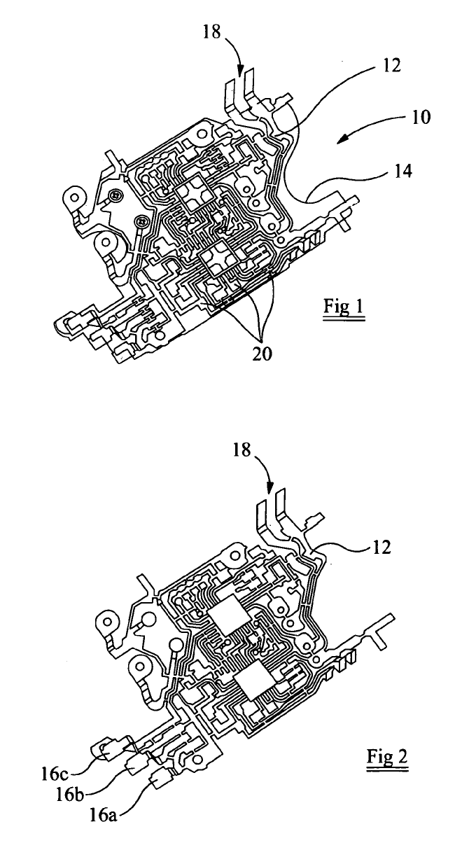

FIG. 1 is a drawing of a three-dimensional circuit substrate according to the present invention;

FIG. 2 is a drawing of an electrically conductive track of a three-dimensional circuit substrate of FIG. 1;

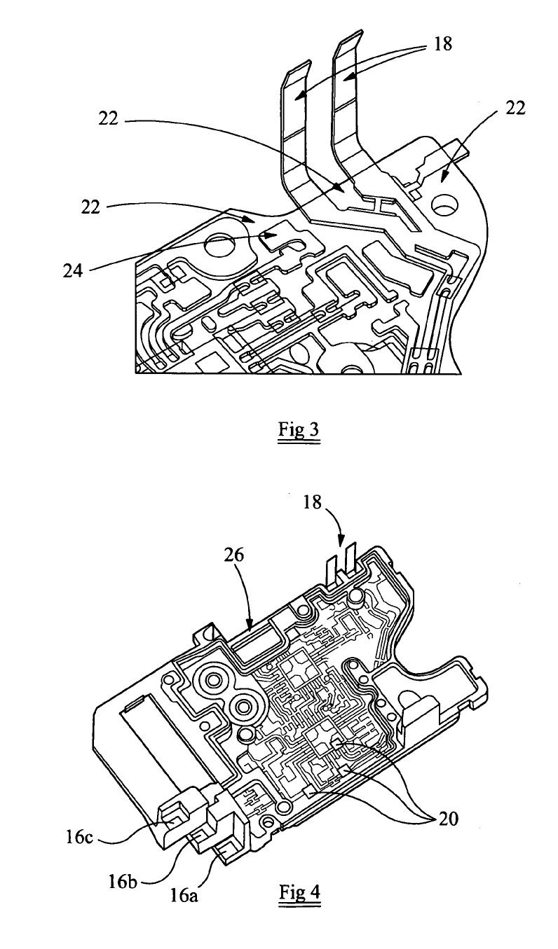

FIG. 3 is a drawing of an enlarged portion of the three-dimensional circuit substrate of FIG. 1;

FIG. 4 is a drawing of the three-dimensional circuit substrate of FIG. 1 having an overmould;

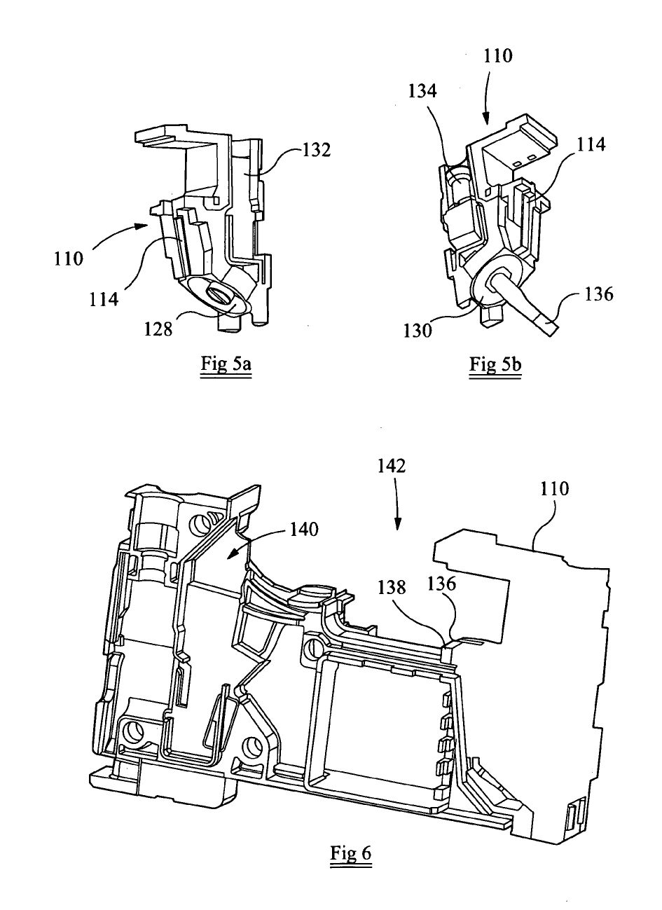

FIGS. 5a and 5b are drawings of a three-dimensional circuit substrate module according to the present invention;

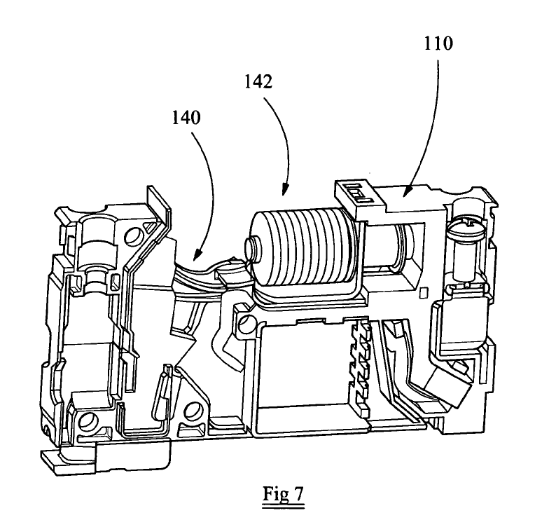

FIG. 6 is a drawing of an intermediate moulding of an electrical device incorporating the electrical circuit module of FIGS. 5a and 5b; and,

FIG. 7 is a drawing of the intermediate moulding of FIG. 6 having additional components.

Referring to FIG. 1, a three-dimensional circuit substrate 10, according to the present invention, comprises an electrically conductive track 12 and a substrate 14 moulded over the electrically conductive track to provide support therefor. The three-dimensional circuit substrate 10 is shown here ready to be populated with electrical components.

Referring also to FIG. 2, the electrically conductive track 12 is formed into a three-dimensional shape corresponding to a predetermined circuit design. The electrically conductive track 12 is formed by punching or stamping the desired three-dimensional shape of a predetermined circuit design out of a sheet of electrically conductive material such as, for example, a copper alloy. The electrically conductive track is approximately in the range of between 0.3 mm and 0.4 mm wide, and preferably approximately 0.35 mm wide. The spacing between adjacent portions of the track is approximately in the range of between 0.38 mm and 0.47 mm, and preferably approximately 0.42 mm.

Alternatively, the electrically conductive track may be formed by etching. In the case of an etched electrically conductive track the width thereof is approximately in the range of between 0.2 mm and 0.3 mm, and preferably approximately 0.25 mm. The spacing between adjacent portions of an etched track is approximately in the range of between 0.18 mm and 0.28 mm, and preferably approximately 0.23 mm.

The thickness of the electrically conductive track is approximately in the range of between 0.1 mm and 0.4 mm, and preferably approximately 0.25 mm. The sheet of electrically conductive material is flattened between rollers to achieve the required thickness and flatness prior to stamping.

Different portions of the electrically conductive track may be formed from different materials and therefore, as will be appreciated, the thicknesses and widths of the track may vary accordingly and in accordance with the application of the electric circuit.

The electrically conductive track 12 may comprise portions raised onto a different plane to provide electrically conductive tracks and terminals 16a, 16b and 16c at a first level, a second level and so on. Other portions of the electrically conductive track 12 may be angled relative to the remainder of the track to provide, for example, electrical test terminals 18. Therefore, a three-dimensional circuit may be formed in the optimal configuration for a particular application.

Once the electrically conductive track has been stamped into the desired three-dimensional form of the predetermined electric circuit design it is disposed in a mould of an injection machine. The mould has a form to correspond to the three-dimensional shape of the electric circuit such that upon injecting the mould with a plastics material, such as an engineering thermoplastic, the substrate 14 is formed over the electrically conductive track 12, as shown in FIG. 1. The support body material should be selected in view of the requirements of the application and the processing technology. However, it is preferable that the support body material has a relatively similar coefficient of thermal expansion to that of the electrically conductive track to minimise mechanical stresses.

The substrate 14 covers the majority of the electrically conductive track 12 except for component apertures 20 which are disposed at predetermined positions overlying the electrically conductive track in accordance with the predetermined circuit design. The component apertures 20 extend through the thickness of the substrate 14 to provide access thereto when populating the electrically conductive track with electric components in accordance with the predetermined circuit design. The substrate 14 supports and stabilises the electrically conductive track 12 to form the three-dimensional circuit substrate 10.

Referring to FIG. 3, the electrically conductive track further comprises anchor portions 22 which are embedded in the moulded substrate 14 to enhance attachment between the electrically conductive track 12 and the substrate 14. FIG. 3 also shows other features such as a test pad 24, for electrically testing the circuit and the previously mentioned electrical test terminals 18

The substrate 14 may comprise further features for location of additional structural, mechanical or electrical components and features such as, for example, seals, attachment means and test points. Alternatively, a second overmould 26 may be formed by injection moulding which provides such features, as shown in FIG. 4.

The second overmould 26 is formed from an engineering thermoplastic material. However, the overmould material should be selected on the requirements of the application and the processing technology. However, it is preferable that the overmould material has a relatively similar coefficient of thermal expansion to that of the electrically conductive track to minimise mechanical stresses.

The substrate 14 or overmould 26 may be shaped to support circuit elements where required and in the case of, for example, high voltage elements, these can be completely embedded in the support body or overmould to provide protection. Examples of other features which may be incorporated in the support body or overmould are: clips; seals; location posts; component housings; latches; and, hinges.

Additionally, the electrically conductive track 12 can be specifically positioned to act as reinforcement and contribute to the overall mechanical strength of the electric circuit.

The electrically conductive track 12 is populated with electrical components, in accordance with the predetermined circuit design, through the component apertures 20. The components are attached to the electrically conductive track using conductive adhesives, solder or welding. The components are preferably surface mount and advantageously attached to the electrically conductive tracks by reflowing the whole substrate 14.

The electrical terminals 16 form electrical connections for interfacing with other electric circuits on different levels or with other components of the same or different electrical device. Therefore, the present invention provides a modular electric circuit system.

Referring to FIGS. 5a and 5b, an electric circuit module 110, according to the present invention, has an electrically conductive track overmoulded with a support body 114. The support body 114 is moulded such that it is structurally functional. The specific example shown in FIGS. 5a and 5b relates to a residual current circuit breaker having a toroidal current sensor. However, it will be appreciated that the present invention is equally applicable to other electrical devices such as, for example, other circuit breakers, residual current devices, ground fault interrupters and arc fault interrupters.

The electric circuit module 110 further comprises a first housing 128, for housing a sensor 130, and a second housing 132 for housing a terminal clamp 134. An electrical conductor 112 extends from the terminal clamp 134, through the sensor 130 and terminates as an electrical terminal 136. The electrical terminal 136 is attachable to an electrical terminal 138 of a second module 140, to provide an electrical device 142, as shown in FIG. 6. FIG. 7 shows an electrical device 142 with other electrical components attached. In this form the electrical device is considered to be at the intermediate moulding stage, requiring a further outer moulding to be completed.

Referring to FIGS. 6 and 7, the second module 140 comprises the main structural elements and the electric circuit module 110 comprises the electrical components. This provides for optimum use of available space and also contributes to the strength and durability of the device as the electrical components are overmoulded in the support body. This is also advantageous because it provides protection for the electrical components against shock, vibration and heat.

Furthermore, having modular circuits allows for selection of specific electronic circuits from a range of different types and configurations. Moreover, the modular circuit also allows sensors, electro mechanical components and electronic components, and the like, to be easily assembled to a specific layer to accommodate the least amount of space.

1. A three-dimensional circuit substrate comprising one or more electrically conductive tracks wherein the substrate is formed from a unitary moulding over the one or more electrically conductive tracks and thereby provides structural support therefor.

2. The three-dimensional circuit substrate as claimed in claim 1, wherein at least one portion of the one or more electrically conductive tracks is disposed on a different plane relative to other portions of the same electrically conductive track.

3. The three-dimensional circuit substrate as claimed in claim 1, wherein at least one portion of the one or more electrically conductive tracks is disposed at an angle relative to one or more other portions of the same electrically conductive track.

4. The three-dimensional circuit substrate as claimed in claim 1, wherein the one or more electrically conductive tracks form one or more three-dimensional electrically conductive tracks having a plurality of levels.

5. The three-dimensional circuit substrate as claimed in claim 4, wherein the external three-dimensional shape of the substrate is determined generally by the peripheral three-dimensional shape formed by the one or more electrically conductive tracks.

6. The three-dimensional circuit substrate as claimed in claim 1, wherein the one or more electrically conductive tracks is formed from a plurality of portions and wherein one or more portions may be formed from different materials and/or thicknesses.

7. The three-dimensional circuit substrate as claimed in claim 1, wherein at least one of the one or more electrically conductive tracks comprises a coin, or localised engraving, to provide a key, or anchor, into the substrate.

8. The three-dimensional circuit substrate as claimed in claim 1, comprising at least one component aperture which extends through the substrate for attachment of an electrical component to one or more of the electrically conductive tracks at a predetermined position thereon.

9. The three-dimensional circuit substrate as claimed in claim 1, comprising location means for determining positional certainty when combining two or more parts to form an electrical device.

10. The three-dimensional circuit substrate as claimed in claim 9 wherein the location means are integrally formed with the substrate.

11. The three-dimensional circuit substrate as claimed in claim 1, comprising attachment means for attaching two or more parts to form an electrical device.

12. The three-dimensional circuit substrate as claimed in claim 11 wherein the attachment means are integrally formed with the substrate.

13. The three-dimensional circuit substrate as claimed in claim 1, wherein at least one of the one or more electrically conductive tracks may be formed to contribute to the structural integrity of the substrate.

14. The three-dimensional circuit substrate as claimed in claim 1, wherein the material from which the, or each, electrically conductive track is formed is of a relatively similar coefficient of thermal expansion as the material from which the substrate is formed.

15. The three-dimensional circuit substrate as claimed in claim 1 wherein the, or each, electrically conductive track is formed from a metal.

16. The three-dimensional circuit substrate as claimed in claim 15 wherein the metal comprises copper.

17. The three-dimensional circuit substrate comprising an electrical circuit as claimed in claim 1.

18. A method of manufacturing a three-dimensional circuit substrate comprising the steps of:
providing an electrically conductive material;
forming the electrically conductive material into one or more electrically conductive tracks of a predetermined circuit design;
providing a mould of a predetermined shape to correspond with the predetermined circuit design; and
moulding a unitary substrate over the electrically conductive tracks to provide support therefor.

19. The method as claimed in claim 18, wherein the step of forming one or more electrically conductive tracks comprises forming at least one portion of the one or more electrically conductive tracks onto a different plane relative to other portions of the same electrically conductive track.

20. The method as claimed in claim 18, wherein at least one portion of the one or more electrically conductive tracks is formed at an angle relative to one or more other portions of the same electrically conductive track.

21. The method as claimed in claim 18, wherein prior to moulding the substrate the one or more electrically conductive tracks are formed into one or more three-dimensional electrically conductive tracks having a plurality of levels.

22. The method as claimed in claim 18, wherein the external three-dimensional external shape of the substrate is determined generally by the peripheral three-dimensional shape provided by the forming of the one or more electrically conductive tracks.

23. The method as claimed in claim 18, wherein the one or more electrically conductive tracks are formed from a plurality of portions wherein one or more portions are formed from different materials and/or thicknesses.

24. The method as claimed in claim 18, wherein prior to the moulding step, a coin or localised engraving may be formed on one or more of the electrically conductive tracks to provide a key, or anchor, into the moulded substrate upon moulding thereof.

25. The method as claimed in claim 18, wherein component attachment means are disposed on the electrically conductive track in predetermined positions to correspond with the predetermined circuit design.

26. The method as claimed in claim 18, wherein the moulding step further comprises forming at least one component aperture in the substrate, which extends through the substrate to provide access for attachment of an electrical component to one or more of the electrically conductive tracks at a predetermined position thereon.

27. The method as claimed in claim 18, wherein the moulding step further comprises forming locating means for determining positional certainty when combining two or more parts to form an electric circuit device.

28. The method as claimed in claim 27 wherein the locating means are integrally formed with the substrate.

29. The method as claimed in claim 27 wherein the locating means are formed as a second moulding.

30. The method as claimed in claim 18 wherein the moulding step further comprises forming attachment means for attaching two or more parts to form an electrical device.

31. The method as claimed in claim 30 wherein the attachment means is integrally formed with the substrate.

32. The method as claimed in claim 30 wherein the attachment means are formed as a second moulding.

33. The method as claimed in claim 18, further comprising populating the electrically conductive track, via at least one component aperture, with electronic components corresponding with the predetermined circuit design.

34. The method as claimed in claim 33 wherein the electronic components are surface mounted.
